(19) United States
(12) Patent Application Publication
(10) Pub. No.: US 2021/0125905 A1
(43) Pub. Date: Apr. 29, 2021

(54) WIRING STRUCTURE AND METHOD FOR MANUFACTURING THE SAME

(71) Applicant: Advanced Semiconductor Engineering, Inc., Kaohsiung (TW)

(72) Inventor: Wen Hung HUANG, Kaohsiung (TW)

(73) Assignee: Advanced Semiconductor Engineering, Inc., Kaohsiung (TW)

(21) Appl. No.: 16/663,087

(22) Filed: Oct. 24, 2019

(51) Int. Cl. H01L 23/498; H01L 23/31; H01L 23/495; H01L 23/532; H01L 23/00

(52) U.S. Cl. CPC H01L 23/49811; H01L 23/49827; H01L 23/3114; H01L 2224/02372; H01L 23/53295; H01L 24/32; H01L 23/49537

(57) ABSTRACT

A wiring structure includes a semiconductor assembly, a conductive structure, an adhesion layer and at least one through via. The semiconductor assembly includes a reconstitution module and a redistribution structure. The reconstitution module includes a plurality of semiconductor elements and an encapsulant. The semiconductor elements are disposed side by side. The encapsulant bonds the semiconductor elements together. The redistribution structure is in direct contact with the reconstitution module. The conductive structure includes at least one dielectric layer and at least one circuit layer in contact with the dielectric layer. The adhesion layer bonds the semiconductor assembly and the conductive structure together. The through via electrically connects the conductive structure and the redistribution structure of the semiconductor assembly.

### BACKGROUND

### 1. Field of the Disclosure

The present disclosure relates to a wiring structure and a manufacturing method, and to a wiring structure including a semiconductor assembly and a conductive structure attached or bonded together by an intermediate layer, and a method for manufacturing the same.

### 2. Description of the Related Art

As for semiconductor packaging method such as package on package (PoP) technology, a plurality of solder elements may be used to electrically connect the packages. However, high-frequency signals can occur serious signal loss after being transmitted through the solder elements, thereby damaging the integrity of the high-frequency signals.

### SUMMARY

In some embodiments, a wiring structure includes a semiconductor assembly, a conductive structure, an adhesion layer and at least one through via. The semiconductor assembly includes a reconstitution module and a redistribution structure. The reconstitution module includes a plurality of semiconductor elements and an encapsulant. The semiconductor elements are disposed side by side. The encapsulant bonds the semiconductor elements together. The redistribution structure is in direct contact with the reconstitution module. The conductive structure includes at least one dielectric layer and at least one circuit layer in contact with the dielectric layer. The adhesion layer bonds the semiconductor assembly and the conductive structure together. The through via electrically connects the conductive structure and the redistribution structure of the semiconductor assembly.

In some embodiments, a wiring structure includes a semiconductor assembly, a low-density stacked structure and an intermediate layer. The semiconductor assembly includes a semiconductor element and a high-density stacked structure. The high-density stacked structure is in direct contact with the semiconductor element. The low-density stacked structure includes at least one dielectric layer and at least one circuit layer in contact with the dielectric layer. The intermediate layer is interposed between the semiconductor assembly and the low-density stacked structure and bonds the semiconductor assembly and the low-density stacked structure together. The low-density stacked structure is electrically connected to the high-density stacked structure of the semiconductor assembly.

In some embodiments, a method for manufacturing a wiring structure includes: (a) providing a semiconductor assembly including a reconstitution module and a redistribution structure in direct contact with the reconstitution module; (b) providing a conductive structure including at least one dielectric layer and at least one circuit layer in contact with the dielectric layer; (c) bonding the semiconductor assembly and the conductive structure together; and (d) electrically connecting the conductive structure and the redistribution structure of the semiconductor assembly.

### BRIEF DESCRIPTION OF THE DRAWINGS

Aspects of some embodiments of the present disclosure are readily understood from the following detailed description when read with the accompanying figures. It is noted that various structures may not be drawn to scale, and dimensions of the various structures may be arbitrarily increased or reduced for clarity of discussion.

FIG. 1 illustrates a cross-sectional view of a wiring structure according to some embodiments of the present disclosure.

FIG. 2 illustrates a cross-sectional view of a wiring structure according to some embodiments of the present disclosure.

FIG. 3 illustrates a cross-sectional view of a wiring structure according to some embodiments of the present disclosure.

FIG. 4 illustrates a cross-sectional view of a wiring structure according to some embodiments of the present disclosure.

FIG. 5 illustrates one or more stages of an example of a method for manufacturing a wiring structure according to some embodiments of the present disclosure.

FIG. 6 illustrates one or more stages of an example of a method for manufacturing a wiring structure according to some embodiments of the present disclosure.

FIG. 7 illustrates one or more stages of an example of a method for manufacturing a wiring structure according to some embodiments of the present disclosure.

FIG. 8 illustrates one or more stages of an example of a method for manufacturing a wiring structure according to some embodiments of the present disclosure.

FIG. 9 illustrates one or more stages of an example of a method for manufacturing a wiring structure according to some embodiments of the present disclosure.

FIG. 10 illustrates one or more stages of an example of a method for manufacturing a wiring structure according to some embodiments of the present disclosure.

FIG. 11 illustrates one or more stages of an example of a method for manufacturing a wiring structure according to some embodiments of the present disclosure.

FIG. 12 illustrates one or more stages of an example of a method for manufacturing a wiring structure according to some embodiments of the present disclosure.

FIG. 13 illustrates one or more stages of an example of a method for manufacturing a wiring structure according to some embodiments of the present disclosure.

FIG. 14 illustrates one or more stages of an example of a method for manufacturing a wiring structure according to some embodiments of the present disclosure.

### DETAILED DESCRIPTION

Common reference numerals are used throughout the drawings and the detailed description to indicate the same or similar components. Embodiments of the present disclosure will be readily understood from the following detailed description taken in conjunction with the accompanying drawings.

The following disclosure provides many different embodiments, or examples, for implementing different features of the provided subject matter. Specific examples of components and arrangements are described below to explain certain aspects of the present disclosure. These are, of course, merely examples and are not intended to be limiting. For example, the formation of a first feature over or on a second feature in the description that follows may include embodiments in which the first and second features are formed or disposed in direct contact, and may also include embodiments in which additional features may be formed or disposed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

At least some embodiments of the present disclosure provide for a wiring structure which may prevent high-frequency signals from occurring transmission loss and maintain the integrity of the high-frequency signals. In some embodiments, the wiring structure includes a semiconductor assembly and a conductive structure attached or bonded together by an intermediate layer. At least some embodiments of the present disclosure further provide for techniques for manufacturing the wiring structure.

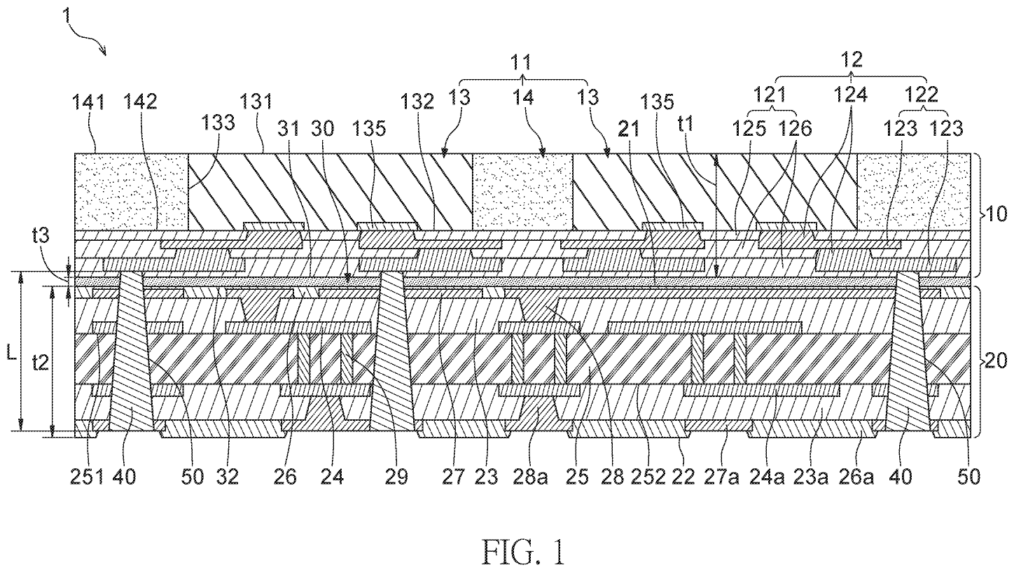

FIG. 1 illustrates a cross-sectional view of a wiring structure 1 according to some embodiments of the present disclosure. The wiring structure 1 includes a semiconductor assembly 10, a conductive structure 20, an intermediate layer 30, at least one through hole 50 and at least one through via 40.

The semiconductor assembly 10 includes a reconstitution module 11 and a redistribution structure 12. In some embodiments, the reconstitution module 11 may include a plurality of semiconductor elements 13 and an encapsulant 14.

The semiconductor element 13 may be, for example, a semiconductor die or a semiconductor chip. The semiconductor elements 13 are disposed side by side. The sizes and functions of the semiconductor elements 13 may be same as or different from each other. In addition, each of the semiconductor elements 13 has a top surface 131 (e.g., a backside surface), a bottom surface 132 (e.g., an active surface) opposite to the top surface 131 and a peripheral surface 133 extending between the top surface 131 and the bottom surface 132. As shown in FIG. 1, each of the semiconductor elements 13 includes a plurality of connecting pads 135 disposed adjacent to and exposed from the bottom surface 132.

The encapsulant 14 may bond the semiconductor elements 13 together, and a material of the encapsulant 14 may be a molding compound with or without fillers. The encapsulant 14 has a top surface 141 and a bottom surface 142 opposite to the top surface 141. The encapsulant 14 may cover at least a portion of each of the semiconductor elements 13. In some embodiments, the encapsulant 14 may cover the peripheral surface 133 of each of the semiconductor elements 13, thus the top surfaces 131 of the semiconductor elements 13 may substantially coplanar with the top surface 141 of the encapsulant 14, and the bottom surfaces 132 of the semiconductor elements 13 may substantially coplanar with the bottom surface 142 of the encapsulant 14.

The redistribution structure 12 is in direct contact with the reconstitution module 11 (including the semiconductor elements 13 and the encapsulant 14). In some embodiments, the redistribution structure 12 may be formed or disposed on the bottom surfaces 132 of the semiconductor elements 13 and the bottom surface 142 of the encapsulant 14. The redistribution structure 12 includes a dielectric structure 121, a redistribution layer 122 and a plurality of inner vias 124. The dielectric structure 121 contacts the encapsulant 14 of the reconstitution module 11 of the semiconductor assembly 10. The dielectric structure 121 may include a first dielectric layer 125 and at least one second dielectric layer 126. The first dielectric layer 125 is disposed on a bottom surface of the reconstitution module 11 to cover the bottom surface 142 of the encapsulant 14 and the bottom surfaces 132 of the semiconductor elements 13. The second dielectric layer 126 is disposed on a bottom surface of the first dielectric layer 125. The first dielectric layer 125 and the second dielectric layer 126 may be made of a cured photoimageable dielectric (PID) material such as epoxy or polyimide (PI) including photoinitiators. The redistribution layer 122 is embedded in the dielectric structure 121 and may include a plurality of circuit layers 123. The inner vias 124 may electrically connect at least one circuit layer 123 or two adjacent circuit layers 123 of the redistribution layer 122. In some embodiments, some of the inner vias 124 are formed on or contact the connecting pads 135 of each of the semiconductor elements 13 directly. Further, the inner vias 124 taper upward. As shown in FIG. 1, the bottommost second dielectric layer 126 may cover the bottommost circuit layer 123. Thus, the bottommost circuit layer 123 may not be exposed from the bottommost second dielectric layer 126.

The redistribution structure 12 may be also referred to as “a stacked structure” or “a high-density conductive structure” or “a high-density stacked structure”. The redistribution layer 122 (including, for example, the two circuit layers 123) of the redistribution structure 12 may be also referred to as “a high-density redistribution layer”. In some embodiments, a density of a circuit line (including, for example, a trace or a pad) of the high-density redistribution layer is greater than a density of a circuit line of a low-density circuit layer (e.g., the circuit layer of the conductive structure 20). That is, the count of the circuit line (including, for example, a trace or a pad) in a unit area of the high-density redistribution layer is greater than the count of the circuit line in an equal unit area of the low-density circuit layer, such as about 1.2 times or greater, about 1.5 times or greater, or about 2 times or greater. Alternatively, or in combination, a line space/line width (L/S) of the high-density redistribution layer is less than an L/S of the low-density circuit layer, such as about 90% or less, about 50% or less, or about 20% or less.

The conductive structure 20 includes at least one dielectric layer (including, for example, one first upper dielectric layer 23, one second upper dielectric layer 26, one first lower dielectric layer 23a and one second lower dielectric layer 26a) and at least one circuit layer (including, for example, one first upper circuit layer 24, one second upper circuit layer 27, one first lower circuit layer 24a and one second lower circuit layer 27a formed of a metal, a metal alloy, or other conductive material) in contact with the dielectric layer (e.g., the first upper dielectric layer 23, the second upper dielectric layer 26, the first lower dielectric layer 23a and the second lower dielectric layer 26a). In some embodiments, the conductive structure 20 may be similar to a core substrate that further includes a core portion 25, and may be in a wafer type, a panel type or a strip type. The conductive structure 20 may be also referred to as “a stacked structure” or “a low-density conductive structure” or “a low-density stacked structure”. The circuit layer (including, for example, the first upper circuit layer 24, the second upper circuit layer 27, the first lower circuit layer 24a and the second lower circuit layer 27a) of the conductive structure 20 may be also referred to as “a low-density circuit layer”. As shown in FIG. 1, the conductive structure 20 has a top surface 21 facing the semiconductor assembly 10 and a bottom surface 22 opposite to the top surface 21. The conductive structure 20 includes a plurality of dielectric layers (for example, the first upper dielectric layer 23, the second upper dielectric layer 26, the first lower dielectric layer 23a and the second lower dielectric layer 26a), a plurality of circuit layers (for example, the first upper circuit layer 24, the second upper circuit layer 27, the first lower circuit layer 24a and the second lower circuit layer 27a) and at least one interconnection via (including, for example, a plurality of upper interconnection vias 28 and a plurality of lower interconnection vias 28a).

In some embodiments, an L/S of the circuit layer (for example, the first upper circuit layer 24, the second upper circuit layer 27, the first lower circuit layer 24a and the second lower circuit layer 27a) of the conductive structure 20 may be greater than the L/S of the redistribution layer 122 of the redistribution structure 12.

The first upper dielectric layer 23 is disposed on a top surface 251 of the core portion 25. The second upper dielectric layer 26 is stacked or disposed on the first upper dielectric layer 23. The second upper dielectric layer 26 is the topmost dielectric layer. In addition, the first lower dielectric layer 23a is disposed on a bottom surface 252 of the core portion 25. The second lower dielectric layer 26a is stacked or disposed on the first lower dielectric layer 23a. The second lower dielectric layer 26a is a bottommost dielectric layer. As shown in FIG. 1, the top surface 21 of the conductive structure 20 is a top surface of the second upper dielectric layer 26, and the bottom surface 22 of the conductive structure 20 is a bottom surface of the second lower dielectric layer 26a.

The first upper circuit layer 24 is formed or disposed on the top surface 251 of the core portion 25, and a portion of the first upper circuit layer 24 is covered by the first upper dielectric layer 23. The second upper circuit layer 27 is formed or disposed on a top surface of the first upper dielectric layer 23, and covered by the second upper dielectric layer 26. The second upper circuit layer 27 is a topmost circuit layer of the conductive structure 20. In some embodiments, the second upper circuit layer 27 is not exposed from the second upper dielectric layer 26. The first lower circuit layer 24a is formed or disposed on the bottom surface 252 of the core portion 25, and a portion of the first lower circuit layer 24a is covered by the first lower dielectric layer 23a. The second lower circuit layer 27a is formed or disposed on a bottom surface of the first lower dielectric layer 23a, and a portion of the second lower circuit layer 27a is covered by the second lower dielectric layer 26a.

In some embodiments, the second upper circuit layer 27 is electrically connected to the first upper circuit layer 24 through the upper interconnection vias 28. That is, the upper interconnection vias 28 are disposed between the second upper circuit layer 27 and the first upper circuit layer 24 for electrically connecting the second upper circuit layer 27 and the first upper circuit layer 24. In some embodiments, the second upper circuit layer 27 and the upper interconnection vias 28 are formed integrally as a monolithic or one-piece structure. Each upper interconnection via 28 tapers downwardly along a direction from the top surface 21 towards the bottom surface 22 of the conductive structure 20.

In some embodiments, the second lower circuit layer 27a is electrically connected to the first lower circuit layer 24a through the lower interconnection vias 28a. That is, the lower interconnection vias 28a are disposed between the second lower circuit layer 27a and the first lower circuit layer 24a for electrically connecting the second lower circuit layer 27a and the first lower circuit layer 24a. In some embodiments, the second lower circuit layer 27a and the lower interconnection vias 28a are formed integrally as a monolithic or one-piece structure. The lower interconnection via 28a tapers upwardly along a direction from the bottom surface 22 towards the top surface 21 of the conductive structure 20.

In some embodiments, the first upper circuit layer 24 may electrically connect the first lower circuit layer 24a through at least one interconnection via 29 extending through the core portion 25. The interconnection via 29, the first upper circuit layer 24 and the first lower circuit layer 24a may be formed integrally and concurrently as a monolithic or one-piece structure.

The intermediate layer 30 is interposed or disposed between the semiconductor assembly 10 and the conductive structure 20 to bond the semiconductor assembly 10 and the conductive structure 20 together. That is, the intermediate layer 30 adheres to the redistribution structure 12 of the semiconductor assembly 10 and the top surface 21 of the conductive structure 20. In some embodiments, the intermediate layer 30 may be an adhesion layer that is cured from an adhesive material (e.g., includes a cured adhesive material such as an adhesive polymeric material). The intermediate layer 30 has a top surface 31 facing the semiconductor assembly 10 and a bottom surface 32 opposite to the top surface 31. The top surface 31 of the intermediate layer 30 contacts the redistribution structure 12 of the semiconductor assembly 10 (that is, the redistribution structure 12 of the semiconductor assembly 10 is attached to the top surface 31 of the intermediate layer 30), and the bottom surface 32 of the intermediate layer 30 contacts the top surface 21 of the conductive structure 20. It is noted that there is no horizontal circuit layer in the intermediate layer 30, and the intermediate layer 30 does not contact the redistribution layer 122 of the redistribution structure 12 and the second upper circuit layer 27 of the conductive structure 20. That is, the redistribution layer 122 and the second upper circuit layer 27 are spaced apart from the intermediate layer 30.

The wiring structure 1 defines a plurality of through holes 50 extending through the conductive structure 20, the intermediate layer 30 and a portion of the dielectric structure 121 of the redistribution structure 12 to expose a portion of the redistribution layer 122. In some embodiments, the through hole 50 may terminate at or on a bottommost circuit layer 123 of the redistribution layer 122 of the redistribution structure 12. That is, the through hole 50 may not extend through the bottommost circuit layer 123 of the redistribution layer 122 of the redistribution structure 12. The through hole 50 may expose a portion of the bottommost circuit layer 123 of the redistribution layer 122 of the redistribution structure 12.

As shown in FIG. 1, the through hole 50 tapers upwardly along a direction from the bottom surface 22 of the conductive structure 20 towards the bottommost circuit layer 123 of the redistribution layer 122 of the redistribution structure 12; that is, a size of a top portion of the through hole 50 is smaller than a size of a bottom portion of the through hole 50. In some embodiments, the through hole 50 may be formed by laser drilling.

The through via 40 is formed or disposed in the through hole 50 and on the exposed portion of the redistribution layer 122 to electrically connect the conductive structure 20 and the redistribution structure 12 of the semiconductor assembly 10. Thus, the through via 40 extends through the conductive structure 20, the intermediate layer 30 and the portion of the dielectric structure 121 of the redistribution structure 12, and is electrically connected to or contacts the exposed portion (e.g., the exposed portion of the bottommost circuit layer 123) of the redistribution layer 122 of the redistribution structure 12. That is, a length L (along a longitudinal axis) of the through via 40 may be greater than a sum of a thickness t2 of the conductive structure 20 and a thickness t3 of the intermediate layer 30. In some embodiments, the thickness t2 of the conductive structure 20 may be greater than a thickness t1 of the semiconductor assembly 10.

As shown in FIG. 1, the through via 40 extends through and contacts the topmost circuit layer (e.g., the second upper circuit layer 27) of the conductive structure 20, and terminates at or on, and contacts the exposed portion of the bottommost circuit layer 123 (e.g., a bottom surface of the bottommost circuit layer 123) of the redistribution layer 122 of the redistribution structure 12. The through via 40 extends from a bottom surface of the second lower circuit layer 27a to the bottom surface of the bottommost circuit layer 123 of the redistribution layer 122. In some embodiments, a low-density circuit layer (e.g., the second upper circuit layer 27) of the low-density stacked structure (e.g., the conductive structure 20) is electrically connected to a high-density redistribution layer (e.g., the redistribution layer 122) of the high-density stacked structure (e.g., the redistribution structure 12) solely by the through via 40 extending through the low-density circuit layer (e.g., the second upper circuit layer 27) of the low-density stacked structure (e.g., the conductive structure 20). Further, the through via 40 tapers upward; that is, a size of a top portion of the through via 40 is smaller than a size of a bottom portion of the through via 40. Thus, a tapering direction of the inner vias 124 of the redistribution structure 12 is the same as a tapering direction of the through via 40. In some embodiments, the through via 40 is a monolithic structure or a one-piece structure having a homogeneous material composition.

As shown in the embodiment illustrated in FIG. 1, the semiconductor assembly 10 is electrically connected to the conductive structure 20 through the through via 40, and no solder element (e.g., solder ball or solder bump) is used in the wiring structure 1, which prevents high-frequency signals from occurring transmission loss and maintains the integrity of the high-frequency signals. In some embodiments, the integrity of the high-frequency signals in the wiring structure 1 at different frequency bands (e.g., 4 Gbps, 6 Gbps and 8 Gbps) may be greater than 80%. Further, a total thickness of the wiring structure 1 is reduced efficiently. In addition, a thermal resistance of the wiring structure 1 is also reduced efficiently.

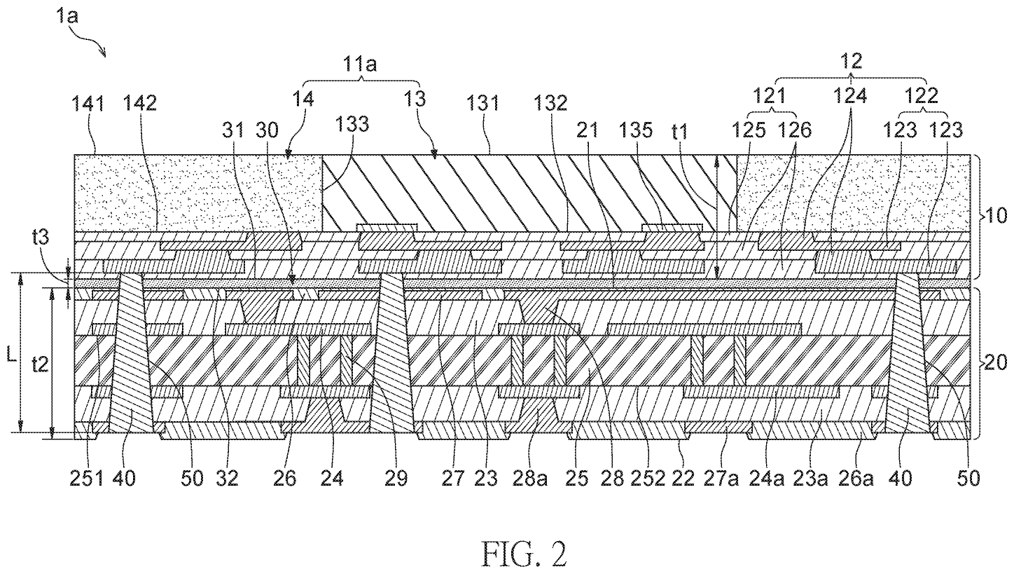

FIG. 2 illustrates a cross-sectional view of a wiring structure 1a according to some embodiments of the present disclosure. The wiring structure 1a is similar to the wiring structure 1 shown in FIG. 1, except for the configuration of the reconstitution module 11a. In some embodiments, an amount of the semiconductor element(s) 13 of the reconstitution module 11a may be reduced to one.

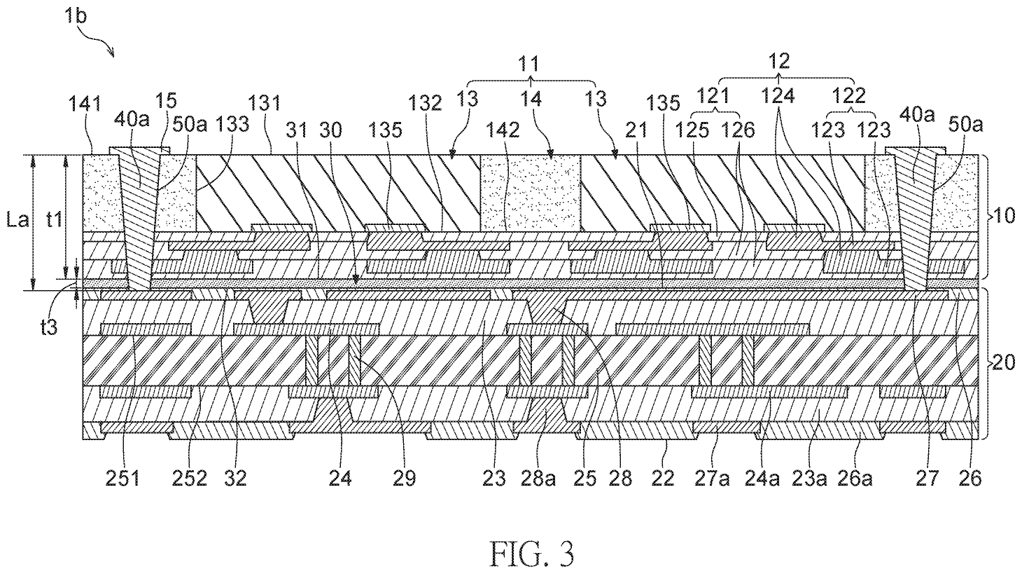

FIG. 3 illustrates a cross-sectional view of a wiring structure 1b according to some embodiments of the present disclosure. The wiring structure 1b is similar to the wiring structure 1 shown in FIG. 1, except for the configurations of the through hole 50a and the through via 40a. In some embodiments, the through hole 50a may extend through the semiconductor assembly 10, the intermediate layer 30 and a portion of the dielectric layer (e.g., the second upper dielectric layer 26) of the conductive structure 20 to expose a portion of the circuit layer (e.g., the second upper circuit layer 27) of the conductive structure 20. In some embodiments, the through hole 50a may extend through the encapsulant 14 of the reconstitution module 11 and the redistribution structure 12. In addition, the through hole 50a may terminate at or on the topmost circuit layer (e.g., the second upper circuit layer 27) of the conductive structure 20. That is, the through hole 50a may not extend through the topmost circuit layer (e.g., the second upper circuit layer 27) of the conductive structure 20. The through hole 50a may expose a portion of the topmost circuit layer (e.g., the second upper circuit layer 27) of the conductive structure 20.

As shown in FIG. 3, the through hole 50a may taper downwardly along a direction from the top surface 141 of the encapsulant 14 towards the topmost circuit layer (e.g., the second upper circuit layer 27) of the conductive structure 20; that is, a size of a top portion of the through hole 50a is greater than a size of a bottom portion of the through hole 50a.

The through via 40a is formed or disposed in the through hole 50a to electrically connect the redistribution structure 12 of the semiconductor assembly 10 and the conductive structure 20. Thus, the through via 40a extends through the semiconductor assembly 10, the intermediate layer 30 and the portion of the dielectric layer (e.g., the second upper dielectric layer 26) of the conductive structure 20, and is electrically connected to or contacts the exposed portion of the circuit layer (e.g., the second upper circuit layer 27) of the conductive structure 20. That is, a length La (along a longitudinal axis) of the through via 40a may be greater than or equal to a sum of a thickness t1 of the semiconductor assembly 10 and a thickness t3 of the intermediate layer 30. In some embodiments, the through via 40a may extend through the encapsulant 14 of the reconstitution module 11 and the redistribution structure 12.

As shown in FIG. 3, the through via 40a extends through and contacts the bottommost circuit layer 123 of the redistribution layer 122 of the redistribution structure 12, and terminates at or on, and contacts the exposed portion of the topmost circuit layer (e.g., a top surface of the second upper circuit layer 27) of the conductive structure 20. The through via 40a extends from the top surface 141 of the encapsulant 14 to a top surface of the topmost circuit layer (e.g., the second upper circuit layer 27) of the conductive structure 20. In some embodiments, a high-density redistribution layer (e.g., the redistribution layer 122) of the high-density stacked structure (e.g., the redistribution structure 12) is electrically connected to a low-density circuit layer (e.g., the second upper circuit layer 27) of the low-density stacked structure (e.g., the conductive structure 20) solely by the through via 40a extending through the high-density redistribution layer (e.g., the redistribution layer 122) of the high-density stacked structure (e.g., the redistribution structure 12). Further, the through via 40a tapers downward; that is, a size of a top portion of the through via 40a is greater than a size of a bottom portion of the through via 40a. Thus, a tapering direction of the inner vias 124 of the redistribution structure 12 is different from a tapering direction of the through via 40a. In some embodiments, the through via 40a is a monolithic structure or a one-piece structure having a homogeneous material composition. The through via 40a may be covered by an outer circuit layer 15 disposed on the encapsulant 14. Alternatively, or in combination, the through via 40a and the outer circuit layer 15 may be formed integrally as a monolithic or one-piece structure.

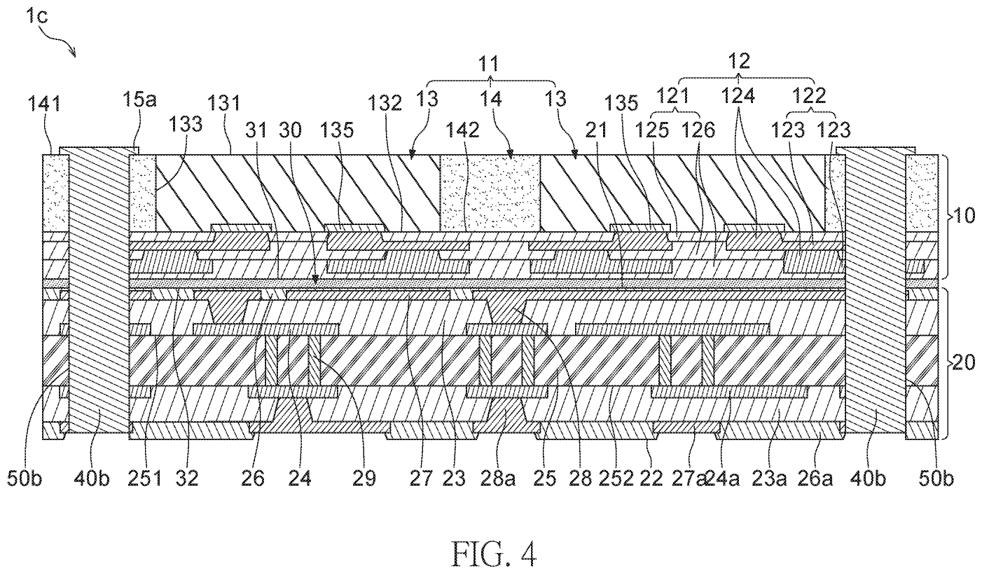

FIG. 4 illustrates a cross-sectional view of a wiring structure 1c according to some embodiments of the present disclosure. The wiring structure 1c is similar to the wiring structure 1b shown in FIG. 3, except for the configurations of the through hole 50b and the through via 40b. In some embodiments, the through hole 50b may extend through the semiconductor assembly 10, the intermediate layer 30 and the conductive structure 20. In some embodiments, the through hole 50b may be formed by mechanical drilling. The through via 40b is formed or disposed in the through hole 50b to electrically connect the redistribution structure 12 of the semiconductor assembly 10 and the conductive structure 20. Thus, the through via 40b extends through the semiconductor assembly 10, the intermediate layer 30 and the conductive structure 20, and is electrically connected to or contacts the redistribution layer 122 of the redistribution structure 12 and the circuit layer (e.g., the second upper circuit layer 27) of the conductive structure 20.

In some embodiments, the through via 40b may extend through and contact the bottommost circuit layer 123 of the redistribution layer 122 and the topmost circuit layer (e.g., the second upper circuit layer 27) of the conductive structure 20. In some embodiments, the through via 40b may further extend through and contact a bottommost circuit layer (e.g., the second lower circuit layer 27a) of the conductive structure 20. The through via 40b extends from the top surface 141 of the encapsulant 14 to a bottom surface of the bottommost circuit layer (e.g., the second lower circuit layer 27a) of the conductive structure 20. In some embodiments, the through via 40b is a monolithic structure or a one-piece structure having a homogeneous material composition. The through via 40b may be covered by an outer circuit layer 15a disposed on the encapsulant 14. Alternatively, or in combination, the through via 40b and the outer circuit layer 15a may be formed integrally as a monolithic or one-piece structure.

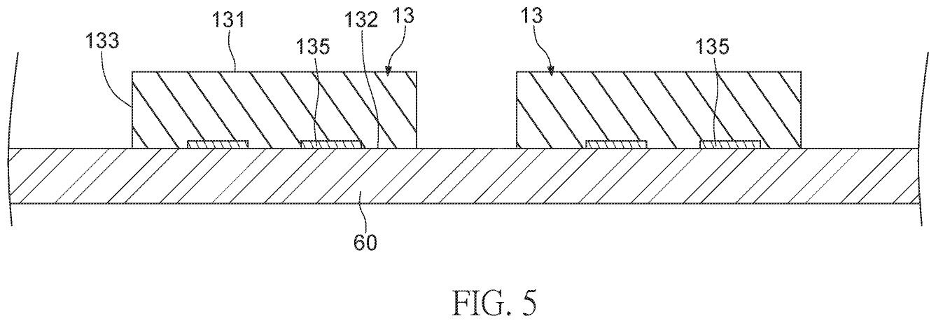

FIG. 5 through FIG. 14 illustrate a method for manufacturing a wiring structure according to some embodiments of the present disclosure. In some embodiments, the method is for manufacturing a wiring structure such as the wiring structure 1 shown in FIG. 1.

Referring to FIG. 5 through FIG. 9 a semiconductor assembly 10 is provided. Referring to FIG. 5, a plurality of semiconductor elements 13 are provided. The semiconductor element 13 may be, for example, a semiconductor die or a semiconductor chip. The semiconductor elements 13 are disposed side by side and on a carrier 60. The sizes and functions of the semiconductor elements 13 may be same as or different from each other. In addition, each of the semiconductor elements 13 has a top surface 131, a bottom surface 132 opposite to the top surface 131 and a peripheral surface 133 extending between the top surface 131 and the bottom surface 132. As shown in FIG. 5, each of the semiconductor elements 13 includes a plurality of connecting pads 135 disposed adjacent to and exposed from the bottom surface 132. In some embodiments, the semiconductor elements 13 may be known good elements that have been tested.

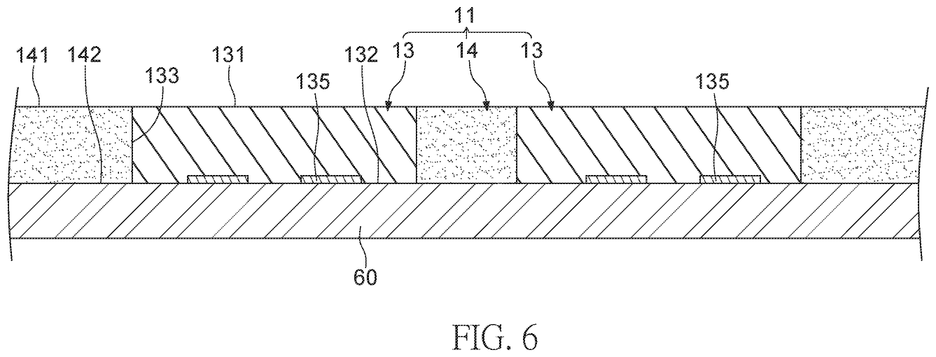

Referring to FIG. 6, an encapsulant 14 is formed or disposed on the carrier 60 to cover at least a portion of the semiconductor elements 13 so as to form a reconstitution module 11. The encapsulant 14 may bond the semiconductor elements 13 together, and a material of the encapsulant 14 may be a molding compound with or without fillers. The encapsulant 14 has a top surface 141 and a bottom surface 142 opposite to the top surface 141. In some embodiments, the encapsulant 14 may cover the peripheral surface 133 of each of the semiconductor elements 13, thus the top surfaces 131 of the semiconductor elements 13 may substantially coplanar with the top surface 141 of the encapsulant 14, and the bottom surfaces 132 of the semiconductor elements 13 may substantially coplanar with the bottom surface 142 of the encapsulant 14.

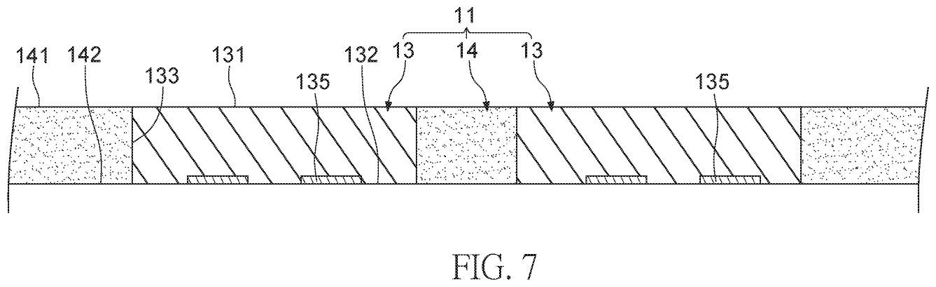

Referring to FIG. 7, the carrier 60 is removed.

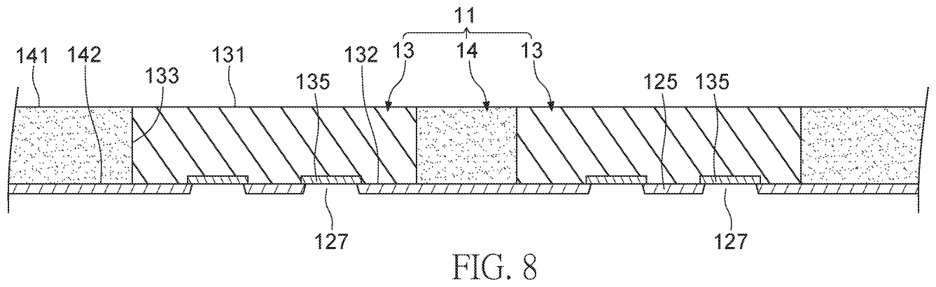

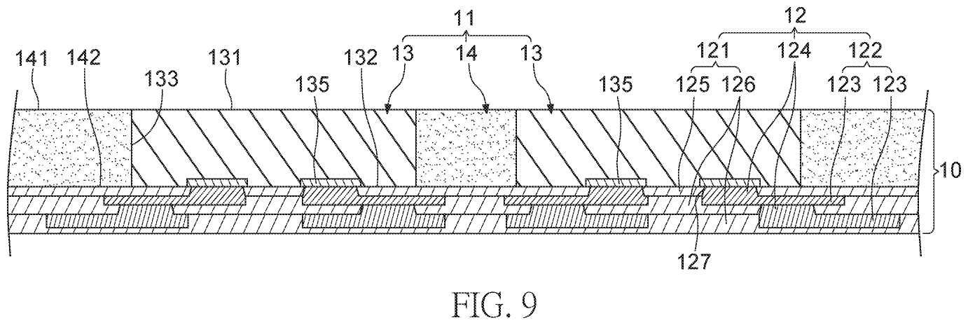

Referring to FIG. 8 through FIG. 9, at least one dielectric structure 121, at least one redistribution layer 122 and a plurality of inner vias 124 are stacked on the reconstitution module 11 to form a redistribution structure 12. Referring to FIG. 8, a first dielectric layer 125 is formed on a bottom surface of the reconstitution module 11. The first dielectric layer 125 may be made of a cured photoimageable dielectric (PID) material such as epoxy or polyimide (PI) including photoinitiators. In some embodiments, the first dielectric layer 125 may cover and contact the bottom surface 142 of the encapsulant 14 and the bottom surfaces 132 of the semiconductor elements 13 directly. Then, a plurality of openings 127 are formed to extend through the first dielectric layer 125 and expose a portion of each of the connecting pads 135.

Referring to FIG. 9, the redistribution layer 122 is formed on a bottom surface of the first dielectric layer 125; the inner vias 124 are formed in the openings 127 of the first dielectric layer 125 and on the exposed portion of each of the connecting pads 135; and at least one second dielectric layer 126 is formed to cover the redistribution layer 122. Thus, the first dielectric layer 125 and the second dielectric layer 126 may constitute the dielectric structure 121. The dielectric structure 121, the redistribution layer 122 and the inner vias 124 may constitute the redistribution structure 12. The redistribution structure 12 is in direct contact with the reconstitution module 11 (including the semiconductor elements 13 and the encapsulant 14), thus the reconstitution module 11 and the redistribution structure 12 may constitute the semiconductor assembly 10.

In some embodiments, the second dielectric layer 126 may be made of a cured photoimageable dielectric (PID) material such as epoxy or polyimide (PI) including photoinitiators. The redistribution layer 122 is embedded in the dielectric structure 121 and may include a plurality of circuit layers 123. The inner vias 124 may be formed between two adjacent circuit layers 123 of the redistribution layer 122 to electrically connect the two adjacent circuit layers 123. Further, the inner vias 124 may taper upward.

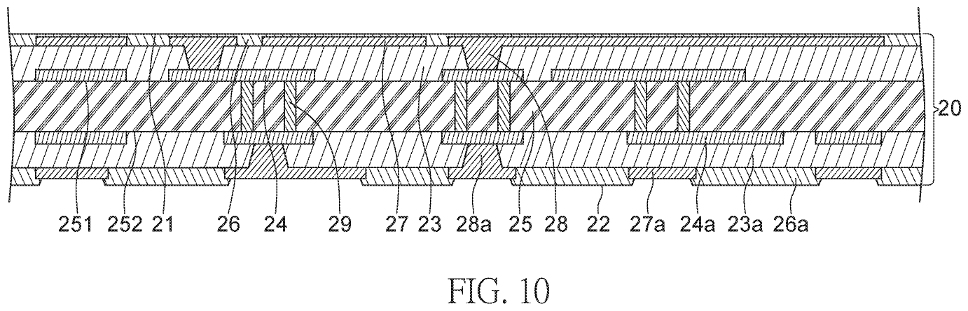

Referring to FIG. 10, a conductive structure 20 is provided. The conductive structure 20 includes at least one dielectric layer (including, for example, one first upper dielectric layer 23, one second upper dielectric layer 26, one first lower dielectric layer 23a and one second lower dielectric layer 26a) and at least one circuit layer (including, for example, one first upper circuit layer 24, one second upper circuit layer 27, one first lower circuit layer 24a and one second lower circuit layer 27a formed of a metal, a metal alloy, or other conductive material) in contact with the dielectric layer (e.g., the first upper dielectric layer 23, the second upper dielectric layer 26, the first lower dielectric layer 23a and the second lower dielectric layer 26a). In some embodiments, the conductive structure 20 may be similar to a core substrate that further includes a core portion 25, and may be in a wafer type, a panel type or a strip type. As shown in FIG. 10, the conductive structure 20 has a top surface 21 and a bottom surface 22 opposite to the top surface 21. The conductive structure 20 includes a plurality of dielectric layers (for example, the first upper dielectric layer 23, the second upper dielectric layer 26, the first lower dielectric layer 23a and the second lower dielectric layer 26a), a plurality of circuit layers (for example, the first upper circuit layer 24, the second upper circuit layer 27, the first lower circuit layer 24a and the second lower circuit layer 27a) and at least one interconnection via (including, for example, a plurality of upper interconnection vias 28 and a plurality of lower interconnection vias 28a).

An L/S of the circuit layer (for example, the first upper circuit layer 24, the first lower circuit layer 24a, the second upper circuit layer 27 and the second lower circuit layer 27a) of the conductive structure 20 may be greater than the L/S of the redistribution layer 122 of the redistribution structure 12 (FIG. 9).

The first upper dielectric layer 23 is formed on a top surface 251 of the core portion 25. The second upper dielectric layer 26 is formed on the first upper dielectric layer 23. The second upper dielectric layer 26 is the topmost dielectric layer. In addition, the first lower dielectric layer 23a is formed a bottom surface 252 of the core portion 25. The second lower dielectric layer 26a is formed on the first lower dielectric layer 23a. The second lower dielectric layer 26a is a bottommost dielectric layer. As shown in FIG. 10, the top surface 21 of the conductive structure 20 is a top surface of the second upper dielectric layer 26, and the bottom surface 22 of the conductive structure 20 is a bottom surface of the second lower dielectric layer 26a.

The first upper circuit layer 24 is formed or disposed on the top surface 251 of the core portion 25, and a portion of the first upper circuit layer 24 is covered by the first upper dielectric layer 23. The second upper circuit layer 27 is formed or disposed on a top surface of the first upper dielectric layer 23, and covered by the second upper dielectric layer 26. The second upper circuit layer 27 is a topmost circuit layer of the conductive structure 20. The first lower circuit layer 24a is formed or disposed on the bottom surface 252 of the core portion 25, and a portion of the first lower circuit layer 24a is covered by the first lower dielectric layer 23a. The second lower circuit layer 27a is formed or disposed on a bottom surface of the first lower dielectric layer 23a, and a portion of the second lower circuit layer 27a is covered by the second lower dielectric layer 26a.

In some embodiments, the second upper circuit layer 27 is electrically connected to the first upper circuit layer 24 through the upper interconnection vias 28. That is, the upper interconnection vias 28 are disposed between the second upper circuit layer 27 and the first upper circuit layer 24 for electrically connecting the second upper circuit layer 27 and the first upper circuit layer 24. In some embodiments, the second upper circuit layer 27 and the upper interconnection vias 28 are formed integrally as a monolithic or one-piece structure. Each upper interconnection via 28 tapers downwardly along a direction from the top surface 21 towards the bottom surface 22 of the conductive structure 20.

In some embodiments, the second lower circuit layer 27a is electrically connected to the first lower circuit layer 24a through the lower interconnection vias 28a. That is, the lower interconnection vias 28a are disposed between the second lower circuit layer 27a and the first lower circuit layer 24a for electrically connecting the second lower circuit layer 27a and the first lower circuit layer 24a. In some embodiments, the second lower circuit layer 27a and the lower interconnection vias 28a are formed integrally as a monolithic or one-piece structure. The lower interconnection via 28a tapers upwardly along a direction from the bottom surface 22 towards the top surface 21 of the conductive structure 20.

In some embodiments, the first upper circuit layer 24 may electrically connect the first lower circuit layer 24a through at least one interconnection via 29 extending through the core portion 25. The interconnection via 29, the first upper circuit layer 24 and the first lower circuit layer 24a may be formed integrally and concurrently as a monolithic or one-piece structure.

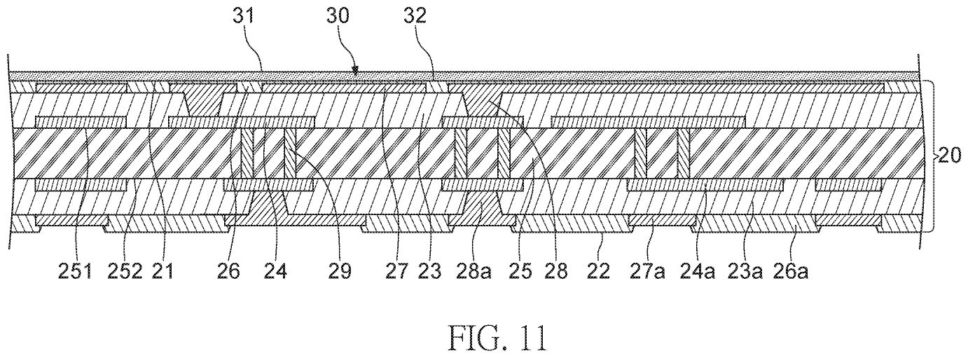

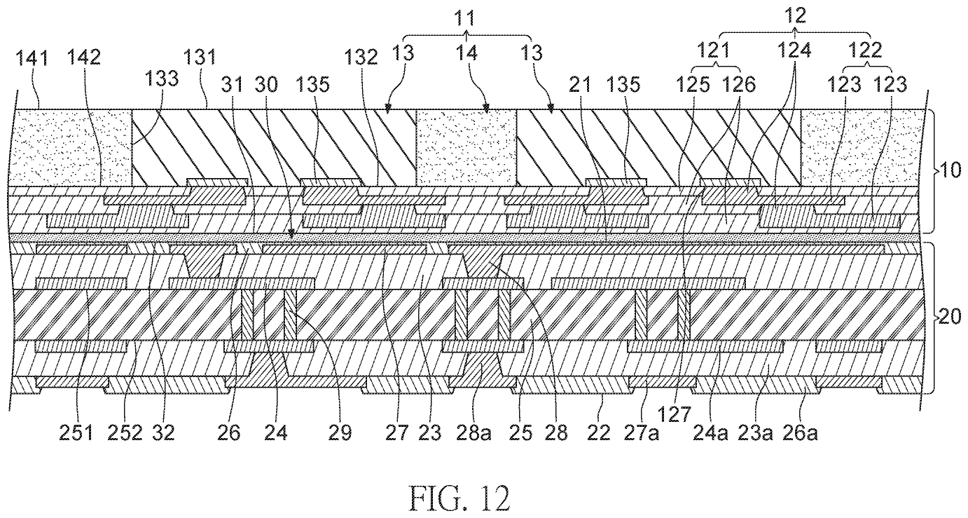

Referring to FIG. 11 through FIG. 12, the semiconductor assembly 10 and the conductive structure 20 are bonded together. Referring to FIG. 11, an adhesion layer 30 is formed or disposed on the conductive structure 20. That is, the adhesion layer 30 adheres to the top surface 21 of the conductive structure 20. In some embodiments, the adhesion layer 30 may be a heat-curable adhesive material or a photo-curable adhesive material. The adhesion layer 30 has a bottom surface 32 attaching the conductive structure 20 and a top surface 31 opposite to the bottom surface 32.

Referring to FIG. 12, the semiconductor assembly 10 and the conductive structure 20 are bonded together through the adhesion layer 30. The top surface 31 of the adhesion layer 30 contacts the redistribution structure 12 of the semiconductor assembly 10 (that is, the redistribution structure 12 of the semiconductor assembly 10 is attached to the top surface 31 of the intermediate layer 30), and the bottom surface 32 of the adhesion layer 30 contacts the top surface 21 of the conductive structure 20. It is noted that there is no horizontal circuit layer in the adhesion layer 30, and the adhesion layer 30 does not contact the redistribution layer 122 of the redistribution structure 12 and the second upper circuit layer 27 of the conductive structure 20. That is, the redistribution layer 122 and the second upper circuit layer 27 are spaced apart from the adhesion layer 30.

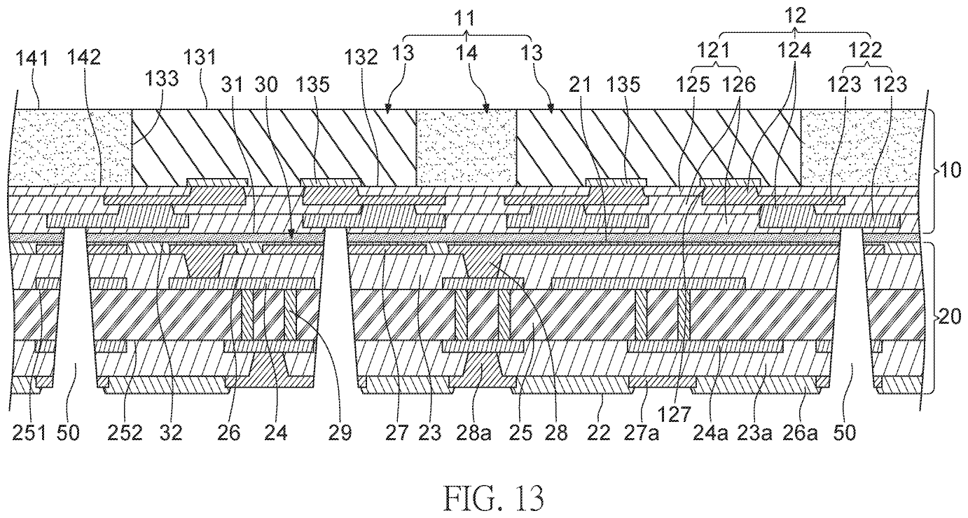

Referring to FIG. 13, at least one through hole 50 is formed to extend through the conductive structure 20, the adhesion layer 30 and a portion of the dielectric structure 121 to expose a portion of the redistribution layer 122 by, for example, laser drilling. In some embodiments, the through hole 50 may terminate at or on a bottommost circuit layer 123 of the redistribution layer 122 of the redistribution structure 12. That is, the through hole 50 may not extend through the bottommost circuit layer 123 of the redistribution layer 122. The through hole 50 may expose a portion of the bottommost circuit layer 123 of the redistribution layer 122.

As shown in FIG. 13, the through hole 50 tapers upwardly along a direction from the bottom surface 22 of the conductive structure 20 towards the bottommost circuit layer 123 of the redistribution layer 122; that is, a size of a top portion of the through hole 50 is smaller than a size of a bottom portion of the through hole 50.

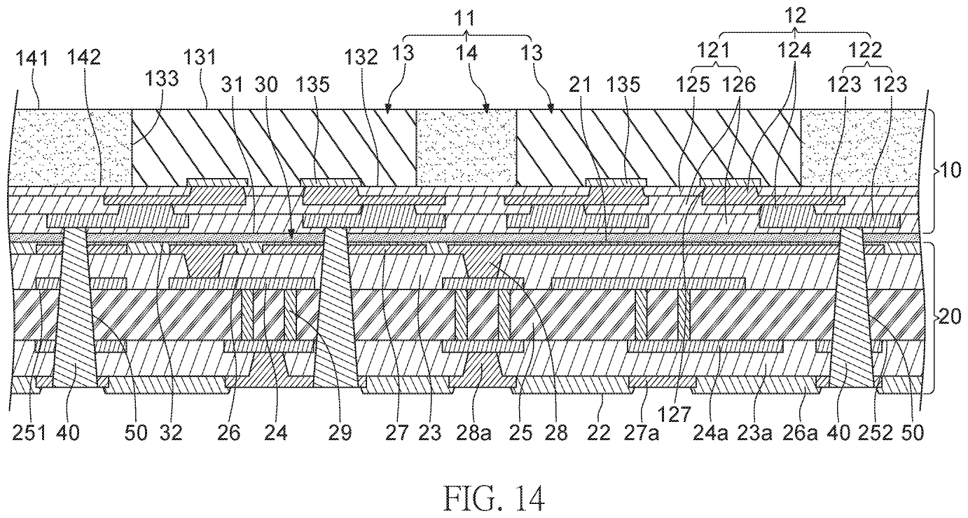

Referring to FIG. 14, at least one through via 40 is formed in the through hole 50 and on the exposed portion (e.g., the exposed portion of the bottommost circuit layer 123) of the redistribution layer 122 to electrically connect the conductive structure 20 and the redistribution structure 12 of the semiconductor assembly 10. Thus, the through via 40 extends through the conductive structure 20, the adhesion layer 30 and the portion of the dielectric structure 121 of the redistribution structure 12, and is electrically connected to or contacts the exposed portion (e.g., the exposed portion of the bottommost circuit layer 123) of the redistribution layer 122 of the redistribution structure 12.

As shown in FIG. 14, the through via 40 extends through and contacts the topmost circuit layer (e.g., the second upper circuit layer 27) of the conductive structure 20, and terminates at or on, and contacts the exposed portion of the bottommost circuit layer 123 (e.g., a bottom surface of the bottommost circuit layer 123) of the redistribution layer 122 of the redistribution structure 12. The through via 40 extends from a bottom surface of the second lower circuit layer 27a to the bottom surface of the bottommost circuit layer 123 of the redistribution layer 122. Further, the through via 40 tapers upward; that is, a size of a top portion of the through via 40 is smaller than a size of a bottom portion of the through via 40. Thus, a tapering direction of the inner vias 124 of the redistribution structure 12 is the same as a tapering direction of the through via 40. In some embodiments, the through via 40 is a monolithic structure or a one-piece structure having a homogeneous material composition.

Then, a singulation process is conducted to obtain a plurality of wiring structures 1 of FIG. 1.

Spatial descriptions, such as “above,” “below,” “up,” “left,” “right,” “down,” “top,” “bottom,” “vertical,” “horizontal,” “side,” “higher,” “lower,” “upper,” “over,” “under,” and so forth, are indicated with respect to the orientation shown in the figures unless otherwise specified. It should be understood that the spatial descriptions used herein are for purposes of illustration only, and that practical implementations of the structures described herein can be spatially arranged in any orientation or manner, provided that the merits of embodiments of this disclosure are not deviated from by such an arrangement.

As used herein, the terms “approximately,” “substantially,” “substantial” and “about” are used to describe and account for small variations. When used in conjunction with an event or circumstance, the terms can refer to instances in which the event or circumstance occurs precisely as well as instances in which the event or circumstance occurs to a close approximation. For example, when used in conjunction with a numerical value, the terms can refer to a range of variation of less than or equal to ±10% of that numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, a first numerical value can be deemed to be “substantially” the same or equal to a second numerical value if the first numerical value is within a range of variation of less than or equal to ±10% of the second numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%.

Two surfaces can be deemed to be coplanar or substantially coplanar if a displacement between the two surfaces is no greater than 5 μm, no greater than 2 μm, no greater than 1 μm, or no greater than 0.5 μm. A surface can be deemed to be substantially flat if a displacement between a highest point and a lowest point of the surface is no greater than 5 μm, no greater than 2 μm, no greater than 1 μm, or no greater than 0.5 μm.

As used herein, the singular terms “a,” “an,” and “the” may include plural referents unless the context clearly dictates otherwise.

As used herein, the terms “conductive,” “electrically conductive” and “electrical conductivity” refer to an ability to transport an electric current. Electrically conductive materials typically indicate those materials that exhibit little or no opposition to the flow of an electric current. One measure of electrical conductivity is Siemens per meter (S/m). Typically, an electrically conductive material is one having a conductivity greater than approximately 10⁴ S/m, such as at least 10⁵ S/m or at least 10⁶ S/m. The electrical conductivity of a material can sometimes vary with temperature. Unless otherwise specified, the electrical conductivity of a material is measured at room temperature.

Additionally, amounts, ratios, and other numerical values are sometimes presented herein in a range format. It is to be understood that such range format is used for convenience and brevity and should be understood flexibly to include numerical values explicitly specified as limits of a range, but also to include all individual numerical values or sub-ranges encompassed within that range as if each numerical value and sub-range is explicitly specified.

While the present disclosure has been described and illustrated with reference to specific embodiments thereof, these descriptions and illustrations are not limiting. It should be understood by those skilled in the art that various changes may be made and equivalents may be substituted without departing from the true spirit and scope of the present disclosure as defined by the appended claims. The illustrations may not be necessarily drawn to scale. There may be distinctions between the artistic renditions in the present disclosure and the actual apparatus due to manufacturing processes and tolerances. There may be other embodiments of the present disclosure which are not specifically illustrated. The specification and drawings are to be regarded as illustrative rather than restrictive. Modifications may be made to adapt a particular situation, material, composition of matter, method, or process to the objective, spirit and scope of the present disclosure. All such modifications are intended to be within the scope of the claims appended hereto. While the methods disclosed herein have been described with reference to particular operations performed in a particular order, it will be understood that these operations may be combined, sub-divided, or re-ordered to form an equivalent method without departing from the teachings of the present disclosure. Accordingly, unless specifically indicated herein, the order and grouping of the operations are not limitations of the present disclosure.

What is claimed is:

1. A wiring structure, comprising:
a semiconductor assembly including:
a reconstitution module including a plurality of semiconductor elements disposed side by side and an encapsulant bonding the semiconductor elements together; and
a redistribution structure in direct contact with the reconstitution module;
a conductive structure including at least one dielectric layer and at least one circuit layer in contact with the dielectric layer;
an adhesion layer bonding the semiconductor assembly and the conductive structure together; and
at least one through via electrically connecting the conductive structure and the redistribution structure of the semiconductor assembly.

2. The wiring structure of claim 1, wherein bottom surfaces of the semiconductor elements are substantially coplanar with a bottom surface of the encapsulant.

3. The wiring structure of claim 1, wherein top surfaces of the semiconductor elements are substantially coplanar with a top surface of the encapsulant.

4. The wiring structure of claim 1, wherein a line space/line width (L/S) of the circuit layer of the conductive structure is greater than an L/S of a redistribution layer of the redistribution structure.

5. The wiring structure of claim 1, wherein the redistribution structure includes a dielectric structure and a redistribution layer embedded in the dielectric structure, and the through via electrically connects the redistribution layer of the redistribution structure.

6. The wiring structure of claim 5, wherein the through via contacts a bottommost circuit layer of the redistribution layer.

7. The wiring structure of claim 5, wherein the redistribution layer is spaced apart from the adhesion layer.

8. The wiring structure of claim 1, wherein the through via extends through the conductive structure and the adhesion layer.

9. The wiring structure of claim 1, wherein a length of the through via is greater than a sum of a thickness of the conductive structure and a thickness of the adhesion layer.

10. A wiring structure, comprising:
a semiconductor assembly including:
a semiconductor element; and
a high-density stacked structure in direct contact with the semiconductor element;
a low-density stacked structure including at least one dielectric layer and at least one circuit layer in contact with the dielectric layer; and
an intermediate layer interposed between the semiconductor assembly and the low-density stacked structure and bonding the semiconductor assembly and the low-density stacked structure together, wherein the low-density stacked structure is electrically connected to the high-density stacked structure of the semiconductor assembly.

11. The wiring structure of claim 10, wherein the semiconductor assembly further includes an encapsulant covering at least a portion of the semiconductor element.

12. The wiring structure of claim 11, wherein a dielectric structure of the high-density stacked structure contacts the encapsulant of the semiconductor assembly.

13. The wiring structure of claim 10, wherein a through via extends through the low-density stacked structure and the intermediate layer.

14. The wiring structure of claim 13, wherein the high-density stacked structure includes a dielectric structure and a redistribution layer embedded in the dielectric structure, and the through via electrically connects the redistribution layer of the high-density stacked structure.

15. The wiring structure of claim 14, wherein the through via contacts a bottommost circuit layer of the redistribution layer.

16. A method for manufacturing a wiring structure, comprising:
(a) providing a semiconductor assembly including a reconstitution module and a redistribution structure in direct contact with the reconstitution module;
(b) providing a conductive structure including at least one dielectric layer and at least one circuit layer in contact with the dielectric layer;
(c) bonding the semiconductor assembly and the conductive structure together; and
(d) electrically connecting the conductive structure and the redistribution structure of the semiconductor assembly.

17. The method of claim 16, wherein (a) includes:
(a1) disposing a plurality of semiconductor elements side by side;
(a2) forming an encapsulant to cover at least a portion of the semiconductor elements so as to form the reconstitution module; and
(a3) stacking at least one dielectric structure and at least one redistribution layer on the reconstitution module to form the redistribution structure.

18. The method of claim 16, wherein (c) includes:
(c1) forming or disposing an adhesion layer on the conductive structure; and
(c2) bonding the semiconductor assembly and the conductive structure together through the adhesion layer.

19. The method of claim 16, wherein (d) is forming at least one through via to electrically connect the conductive structure and the redistribution structure of the semiconductor assembly.

20. The method of claim 19, wherein in (a), the redistribution structure includes a dielectric structure and a redistribution layer embedded in the dielectric structure; wherein (d) includes:
(d1) forming at least one through hole extending through the conductive structure, the adhesion layer and a portion of the dielectric structure to expose a portion of the redistribution layer; and
(d2) forming the through via in the through hole and on the exposed portion of the redistribution layer.
